(19) United States
(12) Patent Application Publication
(10) Pub. No.: US 2025/0376262 A1
(43) Pub. Date: Dec. 11, 2025

(54) SCALABLE INTEGRATED UNPOWERED ENVIRONMENTAL CONTROL MODULE

(71) Applicant: Raytheon Company, Tewksbury, MA (US)

(72) Inventors: Jason M. Ritacco, Murphy, TX (US); Aaron J. Moscho, Frisco, TX (US); Zachary Nathaniel Coker, Allen, TX (US)

(21) Appl. No.: 18/735,857

(22) Filed: Jun. 6, 2024

(51) Int. Cl. B64D 13/08; B64D 13/06; F04D 25/02; F04D 25/06; F04D 25/08; F04D 29/32

(52) U.S. Cl. CPC B64D 13/08; F04D 25/026; F04D 25/06; F04D 25/08; F04D 29/325; B64D 2013/0651

(57) ABSTRACT

An environmental control module (ECM) for an enclosed space includes a heat exchanger having a cooling airflow inlet, a plurality of cold side channels fluidly connected to the cooling airflow inlet to direct the cooling airflow through the enclosed space, and a cooling airflow outlet to remove the cooling airflow from the heat exchanger. A hot side impeller is configured to rotate about a drive axis and is positioned to urge the cooling airflow out of the enclosed space and through the cooling airflow outlet. A cold side impeller is operably connected to and is coaxial with the hot side impeller and is configured to urge the cooling airflow into the heat exchanger via the cooling airflow inlet. A drive secured is to the enclosed space and is operable connected to the hot side impeller to drive rotation of the hot side impeller and the cold side impeller.

### BACKGROUND

The present disclosure relates to environmental control modules for structures, such as enclosed aircraft structures.

Aircraft, such as, for example, helicopters or unmanned aerial vehicles, may include a turret or other enclosed compartment mounted at an exterior of the aircraft having a payload including one or more optical or electronics components therein. The typical turret is disposed in a yoke or other structure that allows for movement of the turret about one or more axes relative to the body of the aircraft. During operation of the aircraft, these payload components require cooling to maintain their operational performance.

Presently, air to air heat exchangers on such turreted systems either take the form a cover with a bolt-in plate-style heat exchanger, with blind mate connectors (easily damaged) and two separate motors to drive fans of the heat exchanger, or structural coldwalls that take up critical volume within the turret.

Other applications incorporate traditional external fins, but these offer limited thermal capacity in conditions with low air flow or zero airspeed.

### SUMMARY

In one exemplary embodiment, an environmental control module (ECM) for an enclosed space includes a heat exchanger having a cooling airflow inlet, a plurality of cold side channels fluidly connected to the cooling airflow inlet to direct the cooling airflow through the enclosed space, and a cooling airflow outlet to remove the cooling airflow from the heat exchanger. A hot side impeller is configured to rotate about a drive axis and is positioned in fluid communication with the cooling airflow outlet to urge the cooling airflow out of the enclosed space and through the cooling airflow outlet. A cold side impeller is operably connected to and is coaxial with the hot side impeller. The cold side impeller is rotatably secured to the heat exchanger and located in fluid communication with the cooling airflow inlet to urge the cooling airflow into the heat exchanger via the cooling airflow inlet. A drive secured is to the enclosed space and is operable connected to the hot side impeller to drive rotation of the hot side impeller and the cold side impeller.

Additionally or alternatively, in this or other embodiments the drive is a brushless drive coil at least partially positioned in a drive pocket defined in the hot side impeller, and energizing of the brushless drive coil urges rotation of at least the hot side impeller about the drive axis.

Additionally or alternatively, in this or other embodiments the brushless drive coil extends through the hot side impeller and at least partially through the cold side impeller, and energizing of the brushless drive coil directly urges rotation of both the hot side impeller and the cold side impeller about the drive axis.

Additionally or alternatively, in this or other embodiments the hot side impeller is operably connected to the cold side impeller via a magnetic coupling such that rotation of the hot side impeller about the drive axis urges rotation of the cold side impeller about the drive axis.

Additionally or alternatively, in this or other embodiments the cold side impeller is rotatably secured to the heat exchanger via a cold side bearing.

Additionally or alternatively, in this or other embodiments the heat exchanger and the cold side impeller are configured to be removed from the enclosed space as a single unit.

Additionally or alternatively, in this or other embodiments both the cold side impeller and the hot side impeller are rotatably secured to the heat exchanger.

Additionally or alternatively, in this or other embodiments the cold side impeller and the hot side impeller are positioned on a common impeller shaft.

Additionally or alternatively, in this or other embodiments the heat exchanger, the cold side impeller and the hot side impeller are configured to be removed from the drive as a single unit.

Additionally or alternatively, in this or other embodiments a hot side bearing is positioned at the heat exchanger to rotatably secure the hot side impeller to the heat exchanger.

Additionally or alternatively, in this or other embodiments one or more of a filter, a particulate getter, and a desiccant are positioned at the heat exchanger to condition the cooling airflow.

In another exemplary embodiment, a turret system of an aircraft includes a turret body, and two side panels positioned at opposing lateral sides of the turret body, the turret body and two side panels defining a payload bay. One or more heat generating components are positioned in the payload bay. One of the two side panels is configured as an environmental control module (ECM) to cool the one or more heat generating components. The ECM includes a heat exchanger having a cooling airflow inlet, a plurality of cold side channels fluidly connected to the cooling airflow inlet to direct the cooling airflow through the payload bay, and a cooling airflow outlet to remove the cooling airflow from the heat exchanger. A hot side impeller is configured to rotate about a drive axis and is positioned in fluid communication with the cooling airflow outlet to urge the cooling airflow out of the payload bay and through the cooling airflow outlet. A cold side impeller is operably connected to and is coaxial with the hot side impeller. The cold side impeller is rotatably secured to the heat exchanger and is positioned in fluid communication with the cooling airflow inlet to urge the cooling airflow into the heat exchanger via the cooling airflow inlet. A drive is secured to the payload bay and is operable connected to the hot side impeller to drive rotation of the hot side impeller and the cold side impeller.

Additionally or alternatively, in this or other embodiments the drive is a brushless drive coil at least partially disposed in a drive pocket defined in the hot side impeller, and energizing of the brushless drive coil urges rotation of at least the hot side impeller about the drive axis.

Additionally or alternatively, in this or other embodiments the brushless drive coil extends through the hot side impeller and at least partially through the cold side impeller, and energizing of the brushless drive coil directly urges rotation of both the hot side impeller and the cold side impeller about the drive axis.

Additionally or alternatively, in this or other embodiments the hot side impeller is operably connected to the cold side impeller via a magnetic coupling such that rotation of the hot side impeller about the drive axis urges rotation of the cold side impeller about the drive axis.

Additionally or alternatively, in this or other embodiments the heat exchanger and the cold side impeller are configured to be removed from the enclosed space as a single unit.

Additionally or alternatively, in this or other embodiments both the cold side impeller and the hot side impeller are rotatably secured to the heat exchanger.

Additionally or alternatively, in this or other embodiments the cold side impeller and the hot side impeller are positioned on a common impeller shaft.

Additionally or alternatively, in this or other embodiments the heat exchanger, the cold side impeller and the hot side impeller are configured to be removed from the drive as a single unit.

Additionally or alternatively, in this or other embodiments a hot side bearing is positioned at the heat exchanger to rotatably secure the hot side impeller to the heat exchanger.

Additional features and advantages are realized through the techniques of the present disclosure. Other embodiments and aspects of the disclosure are described in detail herein and are considered a part of the claimed disclosure. For a better understanding of the disclosure with the advantages and the features, refer to the description and to the drawings.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts:

FIG. 1 is a schematic illustration of an embodiment of an aircraft having a turret structure;

FIG. 2 is a schematic cross-sectional illustration of an embodiment of a turret structure;

FIG. 3 is a schematic illustration of a plurality of cold side channels of an embodiment of a heat exchanger of an environmental control module (ECM);

FIG. 4 is a schematic illustration of a plurality of hot side channels of an embodiment of a heat exchanger of an ECM;

FIG. 5 is a schematic illustration of an exemplary embodiment of an ECM;

FIG. 6 is a schematic illustration of partial disassembly of the embodiment of FIG. 5;

FIG. 7 is a schematic illustration of another exemplary embodiment of an ECM;

FIG. 8 is a schematic illustration of partial disassembly of the embodiment of FIG. 7;

FIG. 9 is a schematic illustration of yet another exemplary embodiment of an ECM;

FIG. 10 is a schematic illustration of partial disassembly of the embodiment of FIG. 9;

FIG. 11 is a schematic illustration of still another exemplary embodiment of an ECM;

FIG. 12 is a schematic illustration of partial disassembly of the embodiment of FIG. 11;

FIG. 13 is a schematic illustration of a hot side of an exemplary embodiment of a heat exchanger of an ECM; and

FIG. 14 is a schematic illustration of a cold side of an exemplary embodiment of a heat exchanger of an ECM.

### DETAILED DESCRIPTION

A detailed description of one or more embodiments of the disclosed apparatus and method are presented herein by way of exemplification and not limitation with reference to the Figures.

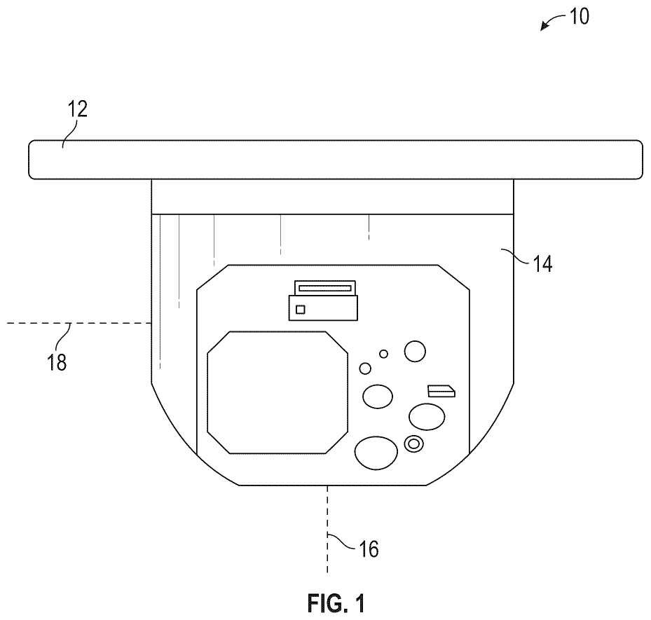

Referring now to FIG. 1, illustrated is an embodiment of an aircraft 10. The aircraft 10 includes a fuselage 12 and a turret 14 mounted thereto. The turret 14 is movable relative to the fuselage 12 about one or more axes of rotation 16 and 18.

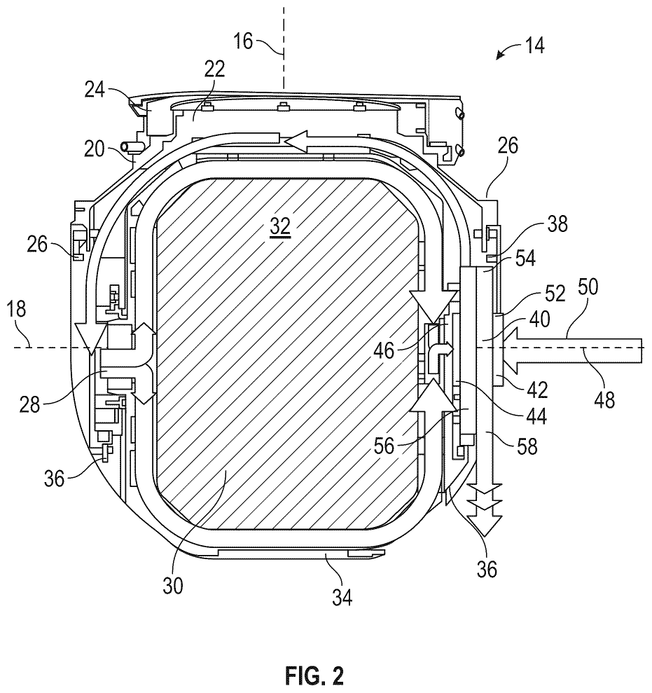

Illustrated in FIG. 2 is a cross-sectional view of an embodiment of the turret 14. The turret 14 is mounted to the fuselage 12 via a yoke 20. The yoke is supportive of the turret 14, and includes a first pivot 22 to rotate the turret 14 about a first axis of rotations 16, such as a yaw axis. The first pivot 22 is located at a yoke base 24, and the yoke 20 includes yoke arms 26 extending from the yoke base 24. In the illustrated embodiment, the turret 14 includes two yoke arms 26 extending in opposite directions from the yoke base 24. In other embodiments, however, the turret 14 may be connected to the yoke 20 via a single yoke arm 26. A second pivot 28 is located at the connection of the yoke arms 26 to the turret 14, and allows for rotation of the turret 14 about a second axis of rotation 18, for example, a pitch axis. The turret 14 includes a payload bay 30 in an interior of the turret 14, and in some embodiments the payload bay 30 includes one or more optical or electronic components, shown schematically at 32, disposed therein. The turret 14 generally includes a turret body 34, and side covers 36 disposed at lateral sides of the turret 14 to enclose the turret 14 when installed to the turret body 34. In some embodiments, the second pivot 28 is located at the side covers 36.

The components 32 in the payload bay 30 require cooling during operation to maintain their performance. To provide this cooling one of the side covers 36 is configured as an environmental control module (ECM) 38. The ECM 38 includes a heat exchanger 40 and two coaxial impellers 42, 44. A brushless coil drive 46 is housed in and fixed in the turret 14 and is operably connected to the impellers 42, 44 to drive the impellers 42, 44 about a drive axis 48. A cold side impeller 42 urges a cooling airflow 50 into an air inlet 52, and through a cold side 54 of the heat exchanger 40. The cooling airflow 50 is circulated through the turret 14 and is urged through a hot side 56 of the heat exchanger 40 via a hot side impeller 44. From the hot side 56, the cooling airflow 50 is exhausted via an air outlet 58.

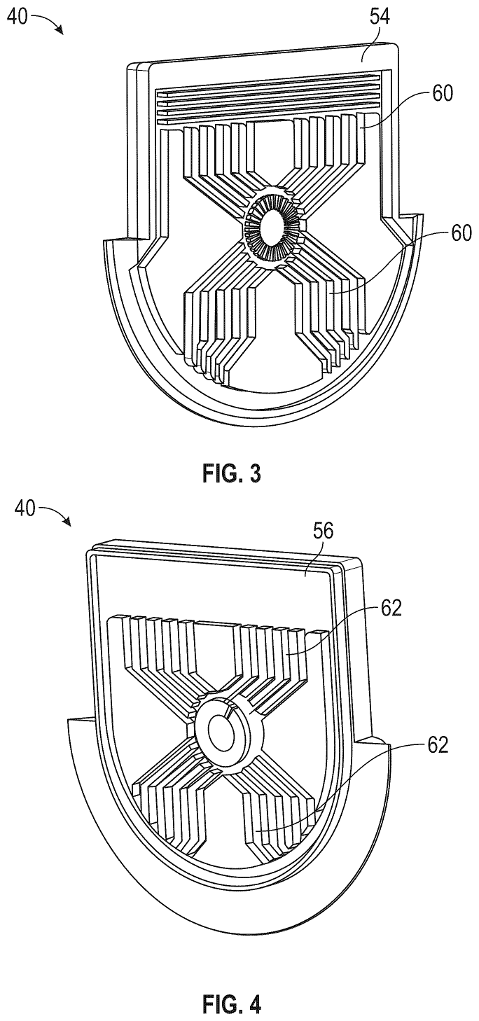

As shown in FIG. 3, the cold side 54 includes a plurality of cold side channels 60 through which the cooling airflow 50 is directed, and as illustrated in FIG. 4 the hot side 56 similarly includes a plurality of hot side channels 62 through which the cooling airflow is directed. One skilled in the art will readily appreciate that the configurations of the cold side channels 60 and the hot side channels 62 illustrated herein are merely exemplary and that in other embodiments other configurations and arrangements of channels 60, 62 may be utilized.

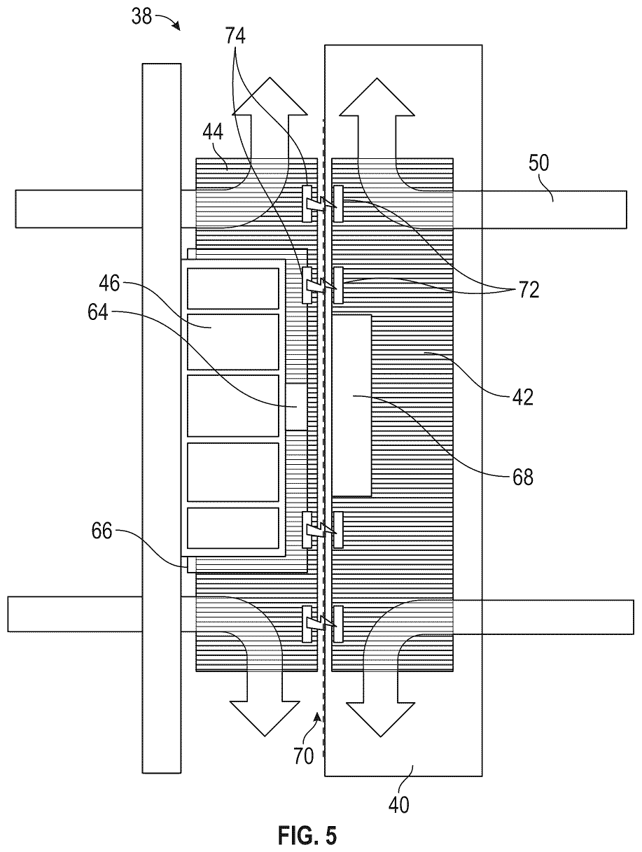

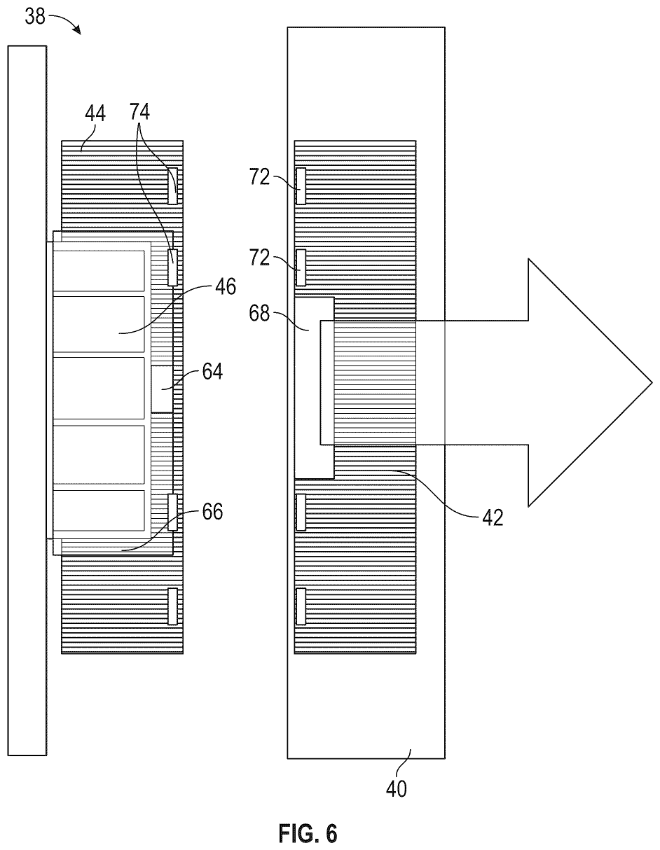

Referring now to FIGS. 5 and 6, illustrated is a cross-sectional view of an exemplary embodiment of an ECM 38 configuration. The hot side impeller 44 is mounted on a hot side bearing 64 concentric with the brushless coil drive 46. In some embodiments, the hot side impeller 44 includes a drive pocket 66 to at least partially receive the brushless coil drive 46 therein. The cold side impeller 42 is mounted on a cold side bearing 68 affixed to the heat exchanger 40, concentric with the hot side bearing 64. The cold side impeller 42 is coupled to the hot side impeller 44 via a magnetic coupling 70, which in some embodiments includes cold side magnets 72 at the cold side impeller 42 and complimentary hot side magnets 74 at the hot side impeller 44. The magnetic coupling 70 thereby interlocks the cold side impeller 42 and the hot side impeller 44 such that when the brushless coil drive 46 is energized, the hot side impeller 44 and the cold side impeller 42 are driven together about the drive axis 48. If the cold side impeller 42 seizes during operation, the hot side impeller 44 is still driven by the brushless coil drive 46, against any magnetic resistance from the magnetic coupling 70. In some embodiments, the heat exchanger 40 together with the cold side impeller 42 is removable from the turret 14 as a unit and replaceable as needed. Further, in some embodiments the hot side impeller 44 is secured to the turret 14 and remains with the turret 14 when the heat exchanger 40 and the cold side impeller 42 are removed.

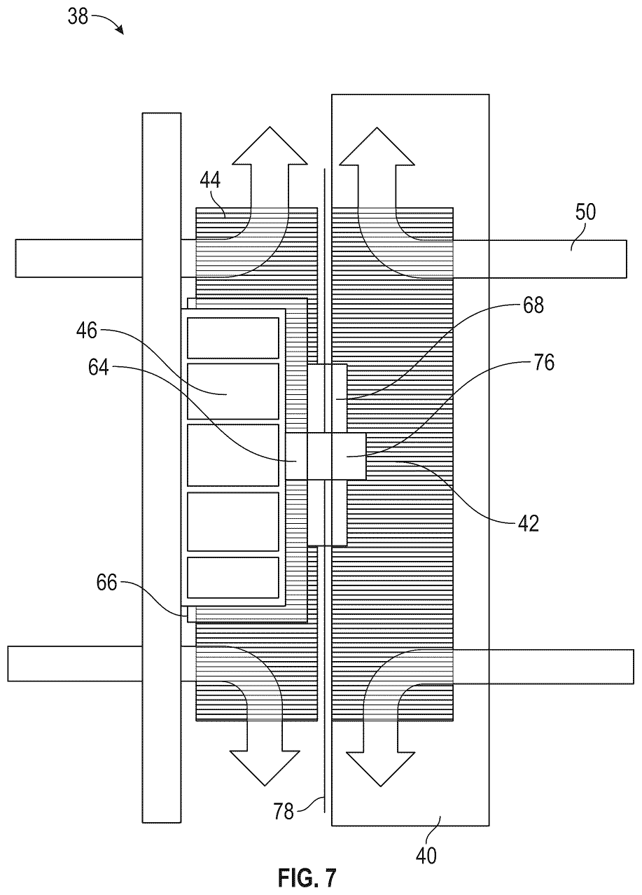

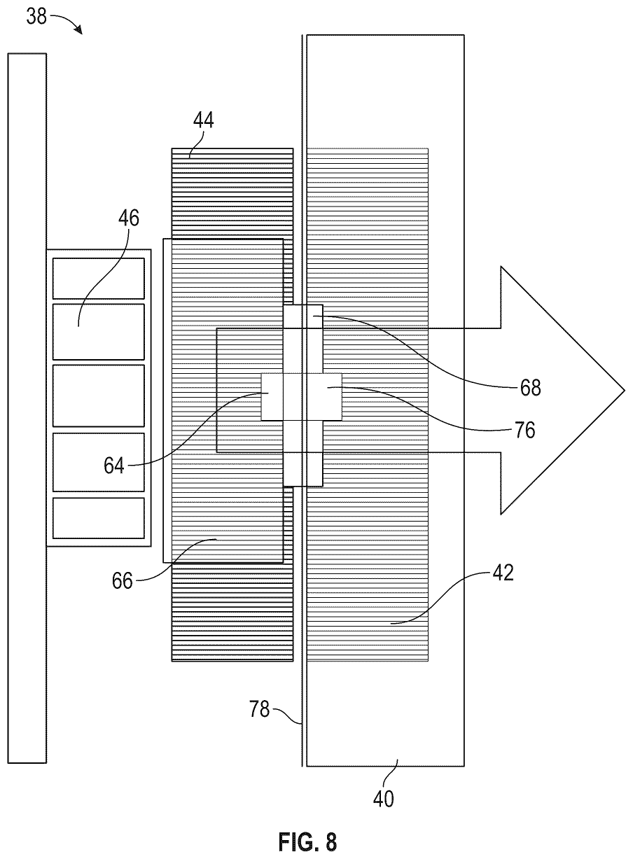

Another exemplary embodiment of an ECM 38 is illustrated in FIGS. 7 and 8. In this embodiment, the impellers 42 and 44 are mounted on a common impeller shaft 76 on opposite sides of a separator wall 78 between the cold side 54 and the hot side 56. The hot side impeller 44 is driven by the brushless coil drive 46 and drives the cold side impeller 42 via the common impeller shaft 76, and therefore the cold side impeller 42 and the hot side impeller 44 always rotate together about the drive axis 48. In this embodiment, both the cold side impeller 42 and the hot side impeller 44 are secured to the heat exchanger 40 such that when the heat exchanger 40 is removed from the turret 14, the cold side impeller 42 and the hot side impeller 44 are also removed from the turret 14.

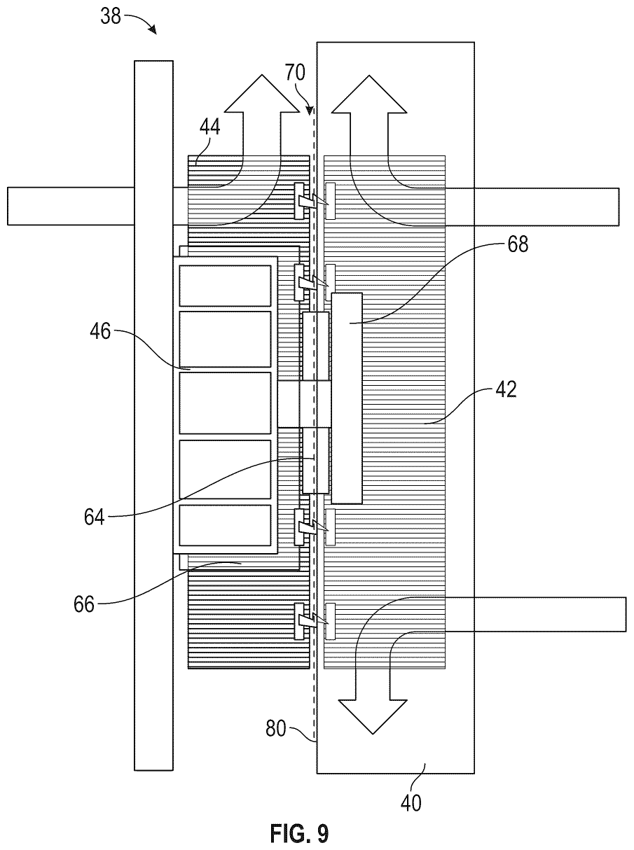

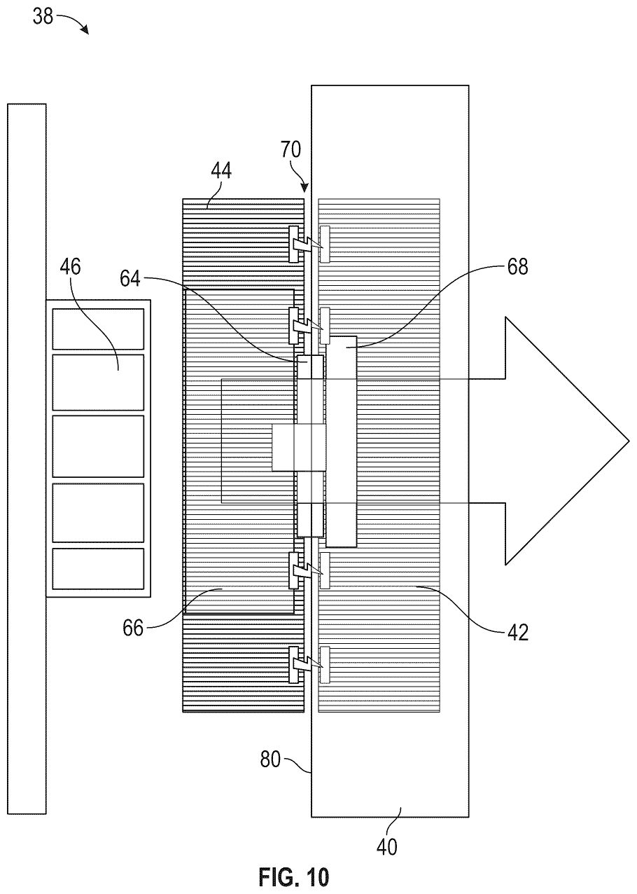

Yet another embodiment is illustrated in FIGS. 9 and 10. In this embodiment, the transfer of rotary motion from the hot side impeller 44 to the cold side impeller 42 is via the magnetic coupling 70. The hot side impeller 44 of this embodiment is rotatably mounted to an inner surface 80 of the heat exchanger 40 via the hot side bearing 64, which in this embodiment is affixed to the heat exchanger 40, and the cold side impeller 42 is mounted to the cold side bearing 68 likewise affixed to the heat exchanger 40. As with other embodiments, energizing the brushless coil drive 46 drives rotation of the hot side impeller 44 which in turn drives rotation of the cold side impeller 42 via the magnetic coupling 70. As illustrated in FIG. 10, both the cold side impeller 42 and the hot side impeller 44 are rotatably secured to the heat exchanger 40, such that when the heat exchanger 40 is removed from the turret 14, both of the cold side impeller 42 and the hot side impeller 44 are automatically removed therewith.

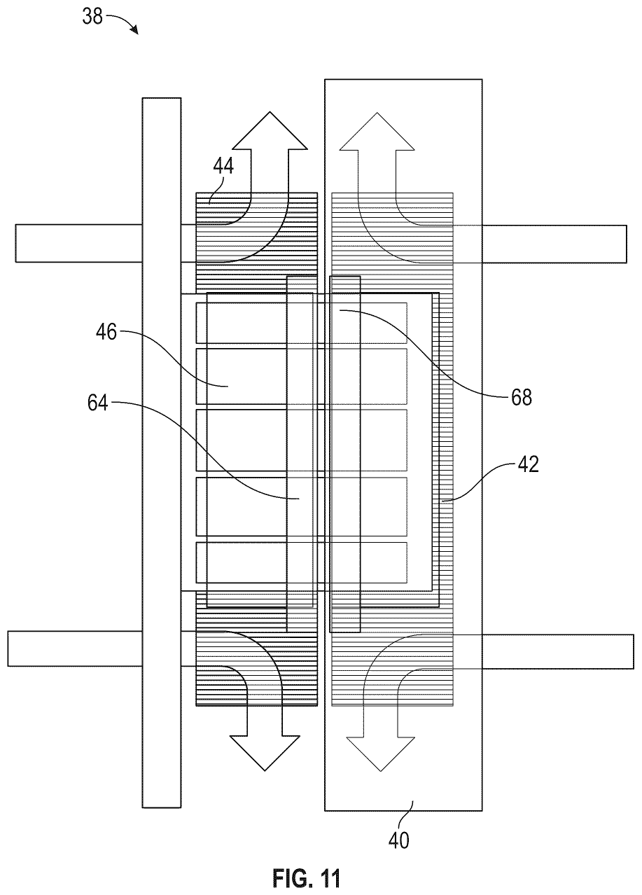

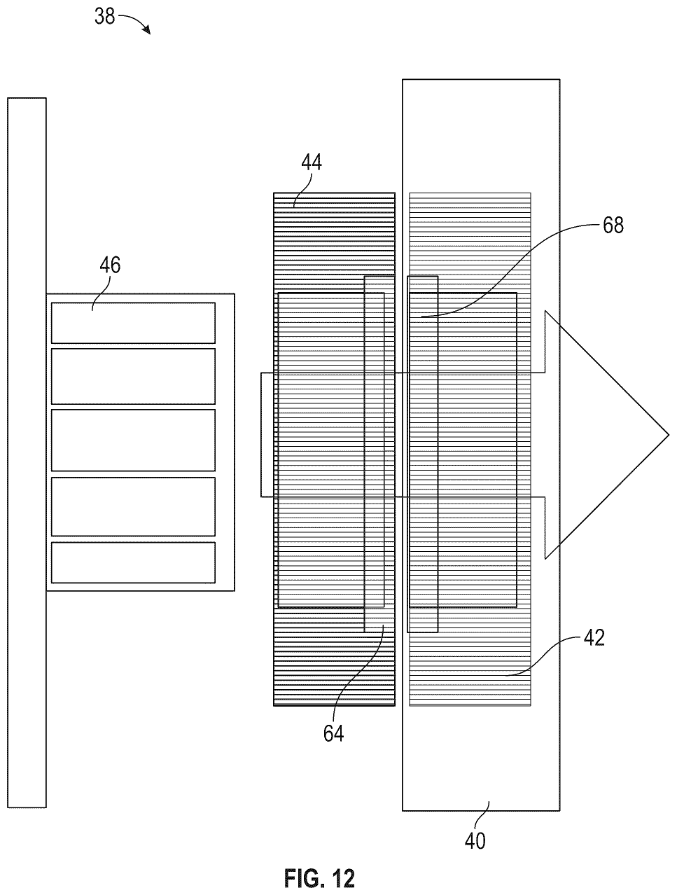

An additional exemplary embodiment is illustrated in FIGS. 11 and 12. In this embodiment, the brushless coil drive 46 is axially extended through the hot side impeller 44 and at least partially through the cold side impeller 42, which are both rotatably mounted on the heat exchanger 40. The brushless coil drive 46 thus directly drives both the cold side impeller 42 and the hot side impeller 44 when energized. In this embodiment, the hot side impeller 44 is free to rotate if the cold side impeller 42 seizes, and likewise the cold side impeller 42 is free to rotate if the hot side impeller 44 seizes. In this embodiment, such as shown in FIG. 12, both the cold side impeller 42 and the hot side impeller 44 are rotatably secured to the heat exchanger 40, such that when the heat exchanger 40 is removed from the turret 14, both of the cold side impeller 42 and the hot side impeller 44 are automatically removed therewith.

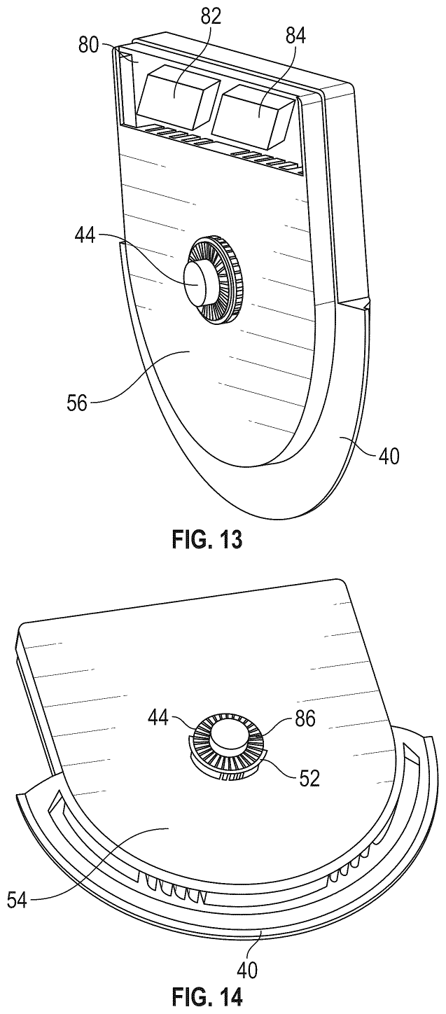

Referring now to FIG. 13, in some embodiments the hot side 56 may include, for example, a pocket 80 in which a particulate collector 82 and/or a desiccant 84 is disposed for cleaning of airflow circulating inside the turret 14. Additionally or alternatively, as illustrated in FIG. 14, one or more filters 86 is located at the air inlet 52 to filter the cooling airflow 50 entering the heat exchanger 40.

Configuration of the ECM 38 disclosed herein separately mount the brushless motor drive 46 and the impellers 42, 44 and in come embodiments utilize the magnetic coupling 70 of the two impellers 42, 44 to effect transfer of force between the impellers 42, 44. By not securing the impellers 42, 44 to the brushless motor drive 46 and mounting them separately to their respective sub-assemblies, service and disassembly are enabled without the need to make or break electrical connections. Further, the cooling airflow is flowed across the gimbal axis of the turret 14, which makes these configurations possible and opens up a large volume of wasted space to be used for cooling.

Additionally, by eliminating active components, such as the brushless motor drive 46 from the serviceable heat exchanger 40, the Environmental Control Module (ECM) 38 can be made completely field serviceable, with much less risk to the system being serviced, including greatly reduced likelihood of FOD introduction, as the main internal volume will be far less exposed during service.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form detailed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the various embodiments with various modifications as are suited to the particular use contemplated.

While the preferred embodiments have been described, it will be understood that those skilled in the art, both now and in the future, may make various improvements and enhancements which fall within the scope of the claims which follow. These claims should be construed to maintain the proper protection for the disclosure as first described.

What is claimed is:

1. An environmental control module (ECM) for an enclosed space, comprising:
a heat exchanger comprising:
a cooling airflow inlet;
a plurality of cold side channels fluidly connected to the cooling airflow inlet to direct the cooling airflow through the enclosed space; and
a cooling airflow outlet to remove the cooling airflow from the heat exchanger;
a hot side impeller configured to rotate about a drive axis and disposed in fluid communication with the cooling airflow outlet to urge the cooling airflow out of the enclosed space and through the cooling airflow outlet;
a cold side impeller operably connected to and coaxial with the hot side impeller, the cold side impeller rotatably secured to the heat exchanger and disposed in fluid communication with the cooling airflow inlet to urge the cooling airflow into the heat exchanger via the cooling airflow inlet; and
a drive secured to the enclosed space and operable connected to the hot side impeller to drive rotation of the hot side impeller and the cold side impeller.

2. The ECM of claim 1, wherein the drive is a brushless drive coil at least partially disposed in a drive pocket defined in the hot side impeller;
wherein energizing of the brushless drive coil urges rotation of at least the hot side impeller about the drive axis.

3. The ECM of claim 2, wherein the brushless drive coil extends through the hot side impeller and at least partially through the cold side impeller;
wherein energizing of the brushless drive coil directly urges rotation of both the hot side impeller and the cold side impeller about the drive axis.

4. The ECM of claim 1, wherein the hot side impeller is operably connected to the cold side impeller via a magnetic coupling such that rotation of the hot side impeller about the drive axis urges rotation of the cold side impeller about the drive axis.

5. The ECM of claim 1, wherein the cold side impeller is rotatably secured to the heat exchanger via a cold side bearing.

6. The ECM of claim 1, wherein the heat exchanger and the cold side impeller are configured to be removed from the enclosed space as a single unit.

7. The ECM of claim 1, wherein both the cold side impeller and the hot side impeller are rotatably secured to the heat exchanger.

8. The ECM of claim 7, wherein the cold side impeller and the hot side impeller are disposed on a common impeller shaft.

9. The ECM of claim 7, wherein the heat exchanger, the cold side impeller and the hot side impeller are configured to be removed from the drive as a single unit.

10. The ECM of claim 7, further comprising a hot side bearing disposed at the heat exchanger to rotatably secure the hot side impeller to the heat exchanger.

11. The ECM of claim 1, further comprising one or more of a filter, a particulate getter, and a desiccant disposed at the heat exchanger to condition the cooling airflow.

12. A turret system of an aircraft, comprising:
a turret body;
two side panels disposed at opposing lateral sides of the turret body, the turret body and two side panels defining a payload bay;
one or more heat generating components disposed in the payload bay;
wherein one of the two side panels is configured as an environmental control module (ECM) to cool the one or more heat generating components, the ECM including:
a heat exchanger comprising:
a cooling airflow inlet;
a plurality of cold side channels fluidly connected to the cooling airflow inlet to direct the cooling airflow through the payload bay; and
a cooling airflow outlet to remove the cooling airflow from the heat exchanger;
a hot side impeller configured to rotate about a drive axis and disposed in fluid communication with the cooling airflow outlet to urge the cooling airflow out of the payload bay and through the cooling airflow outlet;
a cold side impeller operably connected to and coaxial with the hot side impeller, the cold side impeller rotatably secured to the heat exchanger and disposed in fluid communication with the cooling airflow inlet to urge the cooling airflow into the heat exchanger via the cooling airflow inlet; and
a drive secured to the payload bay and operable connected to the hot side impeller to drive rotation of the hot side impeller and the cold side impeller.

13. The turret system of claim 12, wherein the drive is a brushless drive coil at least partially disposed in a drive pocket defined in the hot side impeller;
wherein energizing of the brushless drive coil urges rotation of at least the hot side impeller about the drive axis.

14. The turret system of claim 12, wherein the brushless drive coil extends through the hot side impeller and at least partially through the cold side impeller;
wherein energizing of the brushless drive coil directly urges rotation of both the hot side impeller and the cold side impeller about the drive axis.

15. The turret system of claim 12, wherein the hot side impeller is operably connected to the cold side impeller via a magnetic coupling such that rotation of the hot side impeller about the drive axis urges rotation of the cold side impeller about the drive axis.

16. The turret system of claim 12, wherein the heat exchanger and the cold side impeller are configured to be removed from the enclosed space as a single unit.

17. The turret system of claim 12, wherein both the cold side impeller and the hot side impeller are rotatably secured to the heat exchanger.

18. The turret system of claim 17, wherein the cold side impeller and the hot side impeller are disposed on a common impeller shaft.

19. The turret system of claim 17, wherein the heat exchanger, the cold side impeller and the hot side impeller are configured to be removed from the drive as a single unit.

20. The turret system of claim 17, further comprising a hot side bearing disposed at the heat exchanger to rotatably secure the hot side impeller to the heat exchanger.
